(19) United States
(12) Patent Application Publication
(10) Pub. No.: US 2004/0112289 A1
(43) Pub. Date: Jun. 17, 2004

(54) Thin-film deposition apparatus and method for rapidly switching supply of source gases

(75) Inventors: Shuji Moriya, Nirasaki-Shi (JP); Yasuhiko Kojima, Nirasaki-Shi (JP); Tadahiro Ishizaka, Nirasaki-Shi (JP); Hiroshi Kannan, Tokyo (JP)

Correspondence Address: CROWELL & MORING LLP, INTELLECTUAL PROPERTY GROUP, P.O. BOX 14300, WASHINGTON, DC, 20044-4300, US

(73) Assignee: Tokyo Electron Limited, Minato-ku (JP)

(21) Appl. No.: 10/650,789

(22) Filed: Aug. 29, 2003

(30) Foreign Application Priority Data
Aug. 30, 2002 (JP) NO. 2002-253670

(51) Int. Cl. C23C 16/00

(52) U.S. Cl. 118/715

(57) ABSTRACT

In a thin-film deposition apparatus, a plurality of kinds of source gases are supplied to a reaction chamber one kind at a time by switching the supply of the source gases at high speed so as to reduce a process time. A supply passage is connected to the reaction chamber so as to supply the source gases and an inert gas to the reaction chamber. A source-gas supply opening is provided in the supply passage so as to supply each of the source gases to the supply passage. A source-gas valve is also provided in the supply passage for opening and closing the source-gas supply opening.

### BACKGROUND OF THE INVENTION

1. Field of the Invention

The present invention relates to thin-film deposition techniques and, more particularly, to a thin-film deposition apparatus and method for depositing a thin film onto a substrate placed in a reaction chamber by supplying a plurality of kinds of source gases to the reaction chamber one kind at a time for a plurality of times.

2. Description of the Related Art

With recent progress in miniaturization and densification of semiconductor integrated circuits, it is desired for insulating films and metal wiring films formed on a substrate to achieve a thinner film deposition, a good coverage for a complex configuration, a uniform film deposition macroscopically over an entire wafer, a smooth film deposition microscopically at a nanometer level. As a film deposition method satisfying those requirements, a thin-film deposition method has attracted attention in which a thin film is deposited on a substrate by supplying a plurality of kinds of source gases to the reaction chamber one kind at a time for a plurality of times.

According to such a thin-film deposition method, a film deposition is performed at an atomic layer level or a molecular layer level using adsorption of source gases to a reaction surface so that a thin-film having a predetermined thickness is obtained by repeating those processes.

More specifically, a first source gas is supplied first onto a substrate so as to form an adsorption layer of the source gas on the substrate. Then, the supply of the first source gas is stopped, and the first source gas is evacuated by vacuum or purged by an inert gas. Thereafter, a second source gas is supplied onto the substrate so as to be reacted with the first source gas adsorbed onto the substrate. After stopping the supply of the second gas to the reaction chamber, the second source gas is evacuated by vacuum or purged by and inert gas. A thin film having a predetermined thickness can be obtained by repeating these processes.

Since the first source gas reacts with the second gas after being adsorbed onto the substrate, it can be attempted to reduce a film deposition temperature. Moreover, when forming a film on an inner surface of a hole, deterioration of a coverage due to source gases being reacted and consumed at an upper position of the hole can be avoided, which has been a problem in a conventional chemical vapor deposition (CVD) method. Generally, the thickness of the adsorption layer corresponds to a thickness of a layer of a single atom or molecule, or a layer of two or three atoms or molecules at maximum, and the thickness of the adsorption layer depends on a temperature and a pressure of the process. Therefore, there is a self-conformation in which, if the source gas is supplied by an amount exceeding a necessary amount to form an adsorption layer, an unnecessary amount of the source gas does not stay on the substrate and is exhausted from a reaction chamber. Therefore, it is convenient to control a thickness of an extremely thin film. Moreover, since one time film deposition is performed at an atomic layer level or a molecular layer level, the reaction of the source gases tends to progress completely. Thus, it is preferable that impurities hardly remain in the film.

However, in the thin-film deposition method of depositing a thin film on a substrate by supplying a plurality of kinds of source gases to the reaction chamber one kind at a time for a plurality of times, it requires a long time to perform the film deposition process which repeats supply of each source gas. Therefore, it is necessary to switch a source gas at high speed so as to improve the productivity of film deposition.

FIG. 1 is a structural diagram of an outline of a conventional thin-film deposition apparatus. The thin-film deposition apparatus shown in FIG. 1 forms a thin film on a substrate placed in a reaction chamber by supplying plurality of source gases to the reaction chamber one kind at a time for a plurality of times. As shown in FIG. 1, the conventional thin-film deposition apparatus comprises: a supply source 10 of a first source gas; a supply line 11 and a valve 12, a supply source 20 of an inert gas for the first source gas; a supply line 21 and a valve 22; a supply source 40 of a second source gas; a supply line 41 and a valve 42; a supply source 30 of an inert gas for the second source gas; a supply line 31 and a valve 32; a reaction chamber 50; and an exhaust pump 60.

A substrate 51 which is an object to be processed (processing object) is placed on a support member 52 at a central portion inside the reaction chamber. The first source gas is supplied from the supply source 10 to the reaction chamber 50 by opening the valve 12 provided in the supply line 11. The supplied first source gas is adsorbed onto the substrate 51. After the first source gas is supplied, the valve 12 is closed so as to stop the supply of the first source gas to the reaction chamber 50. However, if the first source gas is stopped by closing the valve 12, the first gas remains in a part of the supply line 11 on the downstream side of the valve 12, that is, a part of the supply line 11 between the valve 12 and the reaction chamber 50. Then, after stopping the supply of the first source gas, an inert gas is supplied from the supply line 20 to the supply line 21 by opening the valve 22 provided in the supply line 21 so as to purge the first source gas remaining in the supply line 11. Thereby, the remaining first source gas is purged and removed from the supply line 21. Supply of the second source gas is performed in the same manner, and the second source gas is also purged from the supply line by an inert gas.

However, in the supply line on the downstream line of the valve 12, it is difficult to remove completely the first source gas which remains in a part of the supply line 11 before converging with the inert gas supply line 21 (indicated by an arrow A in the figure). That is, this portion forms a dead volume in which the remaining gas stays, and the remaining gas may diffuses and enters the reaction chamber 50 while the second source gas is supplied to the reaction chamber 50. The same problem may occur when supplying the second source gas to the reaction chamber 50.

Conventionally, the first source gas or the second source gas is purged by supplying the inert gas only after the supply of the first source gas or the second source gas is stopped. Therefore, the purge of the source gases is not performed rapidly, and it is difficult to alternately switch the source gases at high speed.

### SUMMARY OF THE INVENTION

It is a general object of the present invention to provide an improved and useful thin-film deposition apparatus in which the above-mentioned problems are eliminated.

A more specific object of the present invention is to provide a thin-film deposition apparatus in which a plurality of kinds of source gases are supplied one kind at a time by switching the supply of the source gases at high speed so as to reduce a process time.

In order to achieve the above-mentioned objects, there is provided according to one aspect of the present invention a thin-film deposition apparatus which forms a thin film on a substrate by supplying a plurality of kinds of source gases to a reaction chamber one kind at a time for a plurality of times, comprising: a supply passage connected to the reaction chamber so as to supply the each of the source gases and an inert gas to the reaction chamber; and a source-gas supply opening provided in the supply passage so as to supply each of the source gases to the supply passage; and a source-gas valve for opening and closing the source-gas supply opening provided in the supply passage.

According to the above-mentioned invention, the source-gas supply opening and the source-gas valve are provided in the supply line, and, thus, the source gases can be directly supplied to the supply passage through which the inert gas flows to the reaction chamber. The supply of the source gases to the supply passage can be permitted or inhibited by operations of the source-gas valve. Therefore, a dead volume in which the source gases stay and remain can be eliminated, thereby eliminating diffusion of the source gases from the supply line to the reaction chamber. Therefore, the supply of each source gas can be switched rapidly.

In the thin-film deposition apparatus according to the present invention, the source gases may include a first source gas and a second source gas and the inert gas may include a first inert gas inactive to the first source gas and a second inert gas inactive to the second source gas, and wherein the supply passage may include: a first supply passage connected to the reaction chamber so as to supply the first source gas and the first inert gas to the reaction chamber; and a second supply passage connected to the reaction chamber so as to supply the second source gas and the second inert gas to the reaction chamber, the source-gas supply opening may include: a first source-gas supply opening provided in the first supply passage so as to supply the first source gas to the first supply passage; and a second source-gas supply opening provided in the second supply passage so as to supply the second source gas to the second supply passage, the source-gas valve include: a first source gas valve provided in the first supply passage so as to open and close the first source-gas supply opening; and a second source-gas valve provided in the second supply passage so as to open and close the second source-gas supply opening.

According to the above-mentioned invention, the supply of the first source gas directly to the first supply line can be permitted or prohibited by operation of the first source-gas part, and also the supply of the second source gas directly to the second supply line can be permitted or prohibited by operation of the second source-gas valve. Therefore, a dead volume in which each of the first and second source gases stay and remain can be eliminated, thereby eliminating diffusion of each of the first and second source gases from a part of the supply line to the reaction chamber. Therefore, the supply of the first and second source gases can be alternately switched rapidly.

In the above-mentioned thin-film deposition apparatus, the first supply passage which supplies the first inert gas, may be commonly usable as the second supply passage which supplies the second inert gas.

According to the above-mentioned invention, if the first inert gas and the second inert gas are the same kind of gas, the first supply line can be used as the second supply line. Thus, the number of supply lines can be reduced, which enables miniaturization of the thin-film deposition apparatus.

In the above-mentioned invention, the source-gas valve including the first and second source-gas valves may comprise a diaphragm valve. The use of the diaphragm valve using an easily deformable diaphragm enables a direct and complete closing of the source-gas supply opening including the first and second source-gas supply openings by urging the diaphragm against the source-gas supply opening. Thus, the source-gas supply opening can be surely closed without dead volume in which the source gases can stay and remain, which eliminate diffusion of the source gases from the supply line to the reaction chamber.

Additionally, there is provided according to another aspect of the present invention a thin-film deposition method for depositing a thin film on a substrate placed in a reaction chamber by supplying a plurality of kinds of source gases one kind at a time for a plurality of times, the method comprising continuously supplying an inert gas inactive to the source gases to the reaction chamber while each of the source gases is supplied to the reaction chamber.

According to the above-mentioned invention, the inert gas inactive to the source gases is continuously supplied to the reaction chamber while each of the source gases is supplied to the reaction chamber. That is, the inert gas continuously flows in the supply passage, which enables a rapid purge of the source gas in the supply passage and a valve connected to the supply passage. Thus, the switching of supply of the source gasses can be rapidly performed.

In the thin-film deposition method according to the present invention, the source gases may be supplied to a supply passage used for supplying the inert gas to the reaction chamber so as to supply each of the source gases to the reaction chamber together with the inert gas.

According to the above-mentioned invention, the source-gas supply opening is provided in the supply passage and the inert gas continuously flows in the supply passage. Thus, a dead volume in which the source gas can stay and remain can be eliminated, thereby eliminating diffusion of remaining source gases from the supply passage to the reaction chamber. Thus, the supply of the source gases can be rapidly switched.

In the thin-film deposition method according to the present invention, the source gases may include a first source gas and a second source gas and the inert gas may include a first inert gas which is inactive to the first source gas and a second inert gas which is inactive to the second source gas, and wherein the first inert gas may be continuously supplied to the reaction chamber while the first source gas is supplied to the reaction chamber, and the second inert gas may be continuously supplied to the reaction chamber while the second source gas is supplied to the reaction chamber.

According to the above-mentioned invention, the first inert gas inactive to the first source gas continuously flows to the reaction chamber not only for a period for purging the first gas but also for a period for supplying the first source gas, and the second inert gas inactive to the second source gas continuously flows to the reaction chamber not only for a period for purging the second gas but also for a period for supplying the second source gas. That is, the first inert gas or the second inert gas continuously flows to the reaction chamber, thereby enabling a rapid purge of the supply passage and a valve provided in the supply passage. Thus, switching of the source gases can be rapidly performed.

In the thin-film deposition method according to the present invention, both the first inert gas and the second inert gas may be continuously supplied to the reaction chamber while the first source gas is supplied to the reaction chamber.

According to the above-mentioned invention, the second inert gas inactive to the second source gas continuously flows while the first gas flows in the supply passage to the reaction chamber. Thus, the first gas is prevented from entering the supply line of the second source gas and mixed with the second source gas.

Other objects, features and advantages of the present invention will become more apparent from the following detailed description when read in conjunction with the accompanying drawings.

### BRIEF DESCRIPTION OF THE DRAWINGS

FIG. 1 is a diagram showing an outline of a conventional thin-film deposition apparatus;

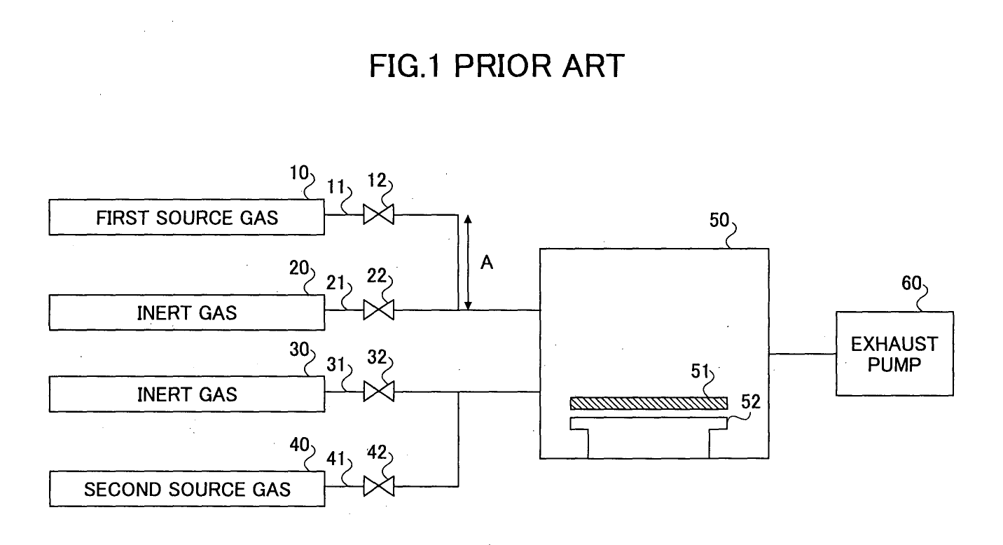

FIG. 2 is a diagram showing an outline of a thin-film deposition apparatus according to an embodiment of the present invention;

FIG. 3 is a cross-sectional view of a source-gas valve shown in FIG. 1 in a state where a source gas is being supplied; and

FIG. 4 is a cross-sectional view of the source-gas valve shown in FIG. 1 in a state where a supply of a source gas is stopped.

### DETAILED DESCRIPTION OF THE PREFERRED EMBODIMENTS

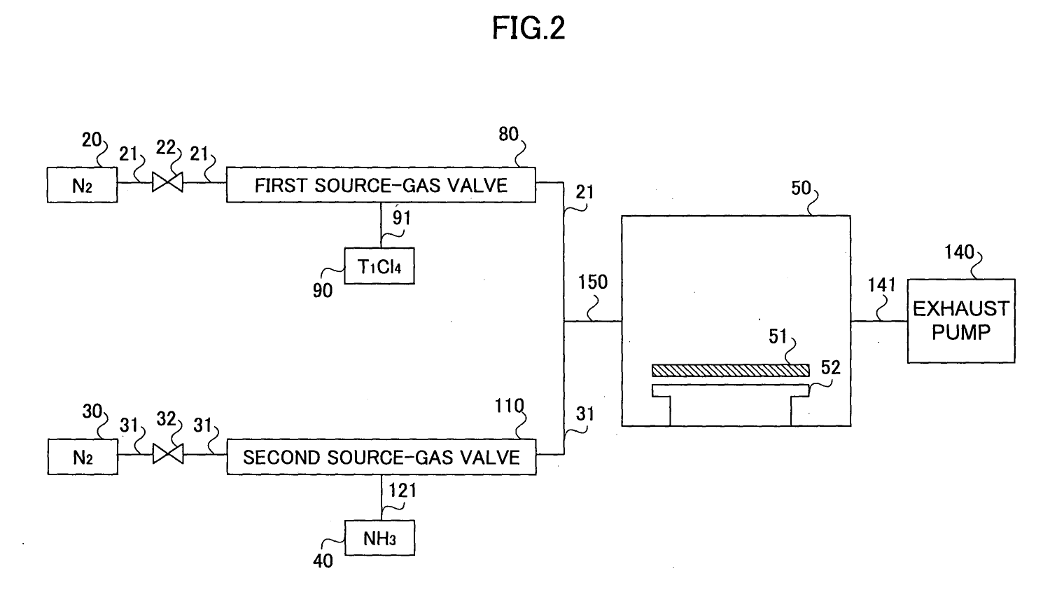

A description will now be given, with reference to FIG. 2, of a thin-film deposition apparatus according to an embodiment of the present invention. FIG. 2 is an outline block diagram of the thin-film deposition apparatus according to the embodiment of the present invention.

The thin-film deposition apparatus of the present embodiment forms or deposits a thin film of titanium nitride on a substrate by supplying alternately a first source gas and a second source gas. The first source gas, which is a vapor gas containing a substance of a thin film to be deposited, is a gas of titanium terachloride (TiCl₄) which is a metal halide having a high melting point. The second source gas is ammonia gas (NH₃) which is reactive with the first source gas. A first inert gas which is nitrogen gas (N₂) is used as a gas inactive to the first source gas. Also a second inert gas which is nitrogen (N₂) gas is used as a gas inactive to the second source gas.

As shown in FIG. 2, the thin-film deposition apparatus according to the embodiment of the present invention comprises: a supply source 10 of TiCl₄ gas which is the first source gas; a supply line 91 of TiCl₄ gas which is the first source gas; a supply source 20 of N₂ gas which is the first inert gas; a supply line 21 of N₂ gas which is the first inert gas; a first source-gas valve 80 provided at an intersection of the supply line 91 and the supply line 21; a supply source 40 of NH₃ gas which is the second source gas; a supply line 121 of NH₃ gas which is the second source gas; a supply source 30 of N₂ gas which is the second inert gas; a supply line 31 of N₂ gas which is the second inert gas; a second source-gas valve 110 provided at an intersection of the supply line 121 and the supply line 31; a reaction chamber 50; and an exhaust pump 140.

Provided in the reaction chamber 50 is a support member 52, which supports a substrate 51 (an object to be processed). A temperature of the support member 52 is adjustable. An exhaust pump 140 such as a dry pump is connected to the reaction chamber 50 via an exhaust pipe 141 and a valve (not shown in the figure) which adjust a flow of exhaust gas. Gases inside the reaction chamber 50 are exhausted to outside by the exhaust pump 140 through the exhaust pipe 141.

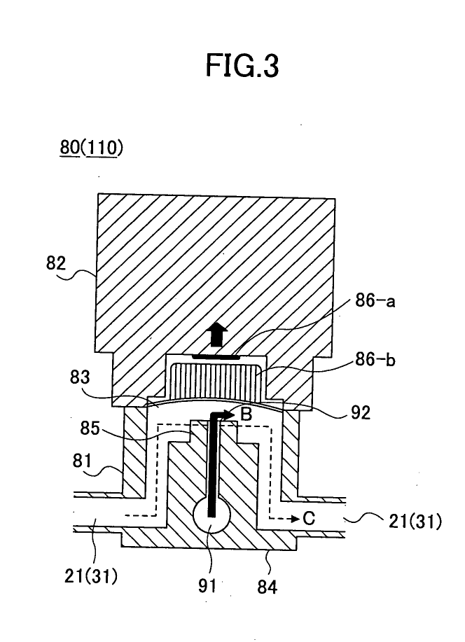

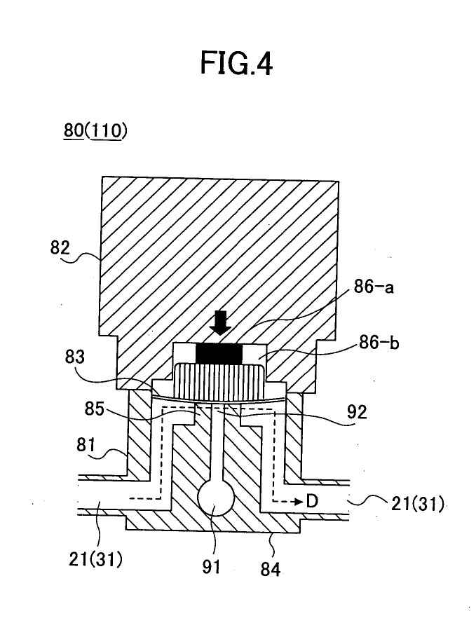

The supply line 91, which is a supply passage to supply TiCl₄ gas, is connected to the supply source 10 of TiCl₄ gas which is the first source gas. The reaction chamber 50 is connected also to the exhaust pump 140, such as a dry pump, through a valve (not shown in the figure), which adjusts a flow of the exhaust gas. The exhaust gas is exhausted by the exhaust pump 140 through an exhaust pipe 141. The supply line 21, which is a supply passage to supply N₂ gas, is connected to the supply source 20 of N₂ gas which is inactive to the first source gas. A valve 22 is provided on the supply line 21 so as to open or close the supply line to permit or prohibit the supply of N₂ gas through the supply line 21. A part of the supply line 21 on the downstream side of the valve 22 converges with a supply line 91, which is a supply passage to supply TiCl₄ gas, via a first source-gas valve 80. The supply line 21, which is converged with the supply line 91, is connected to a supply pipe 150, which is a supply passage connected to the reaction chamber 50 at the downstream end thereof. It should be noted that a structure of the source-gas valve 80 will be explained later with reference to FIG. 3 and FIG. 4.

Similarly, the supply line 121, which is a supply passage to supply NH₃ gas, is connected to the supply source 40 of NH₃ gas which is the second source gas. The supply line 31, which is a supply passage to supply N₂ gas, is connected to the supply source 30 of N₂ gas which is inactive to the second source gas. A valve 32 is provided on the supply line 31 so as to open or close the supply line to permit or prohibit the supply of N₂ gas through the supply line 31. A part of the supply line 31 on the downstream side of the valve 32 converges with a supply line 121, which is a supply passage to supply NH₃ gas, via a second source-gas valve 110. The supply line 31, which is converged with the supply line 121, is connected to the supply pipe 150, which is a supply passage connected to the reaction chamber 50 at the downstream end thereof.

A description will be given, with reference to FIGS. 3 and 4, of a structure of each of the first and second source-gas valves 80 and 110. Here, since the first source-gas valve 80 (hereinafter simply referred to as a valve 80) and the second source-gas valve 110 (hereinafter simply referred to as a valve 110) have the same structure and the same action, a description of the valve 110 will be omitted.

FIG. 3 is a cross-sectional view of the valve 80 (110) when the source gas is supplied, that is, when the supply of the source gas is permitted by opening the valve. FIG. 4 is a cross-sectional view of the valve 80 (110) when the source gas is not supplied, that is, the supply of the source gas is prohibited by closing the valve.

Referring to FIG. 3 and FIG. 4, the valve 80 comprises a first valve housing 81 and a second valve housing 82 connected to the first valve housing 81. A box member 84 is arranged at the center inside the first valve housing 81. In the first valve housing 81, the supply line 21 of N₂ gas enters the first valve housing 81 from one side of the first valve housing 81, extends along sidewalls and upper face of the box member 84, and extends out of the first valve housing 81 from the other side of the first housing 81. A diaphragm 83 formed of an easily deformable material, such as a thin plate of a circular wavy shape or an elastic tube, is provided in an upper portion of the supply line 21 of N₂ gas provided along the upper face of the box member 84.

A protruding part 85 is provided in the center of the upper face of the box member 84. The box member 84 is provided with the supply line of TiCl₄ gas at the center thereof. An end of the supply line 91 of TiCl₄ gas is connected to a part of the supply line 21 extending along the upper face of the box member 84 at the top upper surface of the protruding part 85 so as to serve as a first source-gas supply opening 92

A diaphragm urging mechanism 86-a, 86-b is provided in the second valve housing 82 so as to move the diaphragm 83 toward the box member 84 or the protruding part 85. The diaphragm urging mechanism 86-a, 86-b urges or deforms the diaphragm 83 based on an output signal of a central processing unit of a computer (not shown in the figure) through a signal converter (not shown in the figure) using an electromagnetic force or an air pressure as a drive power. When the diaphragm urging mechanism urges the diaphragm 83 in a direction opposite to a direction toward the box member 84, the first source-gas supply opening 92 on the upper surface of the protruding part 85 is opened so that the supply line 91 of TiCl₄ gas is connected with the supply line 21 of N₂ gas.

On the other hand, when the diaphragm moving mechanism urges the diaphragm 83 in a direction toward the box member 84, the first source-gas supply opening 92 on the upper surface of the protruding part 85 is closed so that the supply line 91 of TiCl₄ gas is disconnected from the supply line 21 of N₂ gas.

A description will now be give, with reference to FIGS. 2, 3 and 4, of a flow of each gas in a film deposition process performed by the thin-film deposition apparatus according to the present embodiment.

In the thin-film deposition apparatus according to the present embodiment, TiCl₄ gas is supplied first to the reaction chamber 50 so as to form an adsorption layer of the TiCl₄ gas, which is the first source gas, on the substrate 51 placed on the support member 52 in the reaction chamber 50. Additionally, N₂ gas is introduced from the supply sources 20 and 30 to the supply lines 21 and 31, respectively.

At this time, if the diaphragm urging mechanism 86-a, 86-b urges the diaphragm 83 in the direction toward the box member 84, the first source-gas supply opening 92 is opened to the supply line 21 of N₂ gas. Thus, TiCl₄ gas supplied by the supply source 10 and flowing through the supply line 91 is supplied to the supply line 21 of N₂ gas via the first source-gas supply opening 92 which is opened. Namely, the TiCl₄ gas flows in a direction of arrow B in FIG. 3.

On the other hand, N₂ gas supplied by the supply source 20 is continuously supplied to the supply line 21 and continuously flows through the supply line 21. That is, the N₂ gas, which corresponds to the first inert gas, flows continuously in a direction of arrow C indicated by dotted lines in FIG. 3.

Therefore, the TiCl₄ gas and the N₂ gas are mixed within the supply line 21. The supply line 21 is connected to the supply pipe 150, which is connected to the reaction chamber 50 on the downstream side, and thereby, the TiCl₄ gas and the N₂ gas are supplied to the reaction chamber 50 through the supply pipe 150.

Moreover, since N₂ gas is continuously supplied from the supply source 30 to the supply line 31 at the same time, the TiCl₄ gas, which is the first source gas, is prevented from entering the supply line 121 of NH₃ gas, which is the second source gas, thereby preventing mixture of both the first and second source gases.

Next, as shown in FIG. 4, the supply of the TiCl₄ gas, which is the first source gas, to the reaction chamber 50 is stopped, and the TiCl₄ gas is purged by N₂ gas from the supply source 20. That is, only N₂ gas is supplied through the supply line 21 and the supply pipe 150.

At this time, when purging the TiCl₄ gas, the diaphragm urging mechanism 86-a, 86-b urges the diaphragm 83 in the direction toward the box member 84 as shown in FIG. 4 so as to directly and completely close the first source-gas supply opening 92, which is open in the top surface of the protruding part 85 and communicates the supply line 91 of TiCl₄ gas with the supply line 21 of N₂ gas. Accordingly, the TiCl₄ gas cannot flow into the supply line 21 through the first source-gas supply opening 92.

On the other hand, N₂ gas continuously flows through the supply line 21 and the supply pipe 150, as is in the case shown in FIG. 3. That is, N₂ gas, which corresponds to the first inert gas, flows around the protruding part 85 in which the first source-gas opening 92 is formed, and flows continuously in a direction of arrow D indicated by dotted lines in FIG. 4.

Therefore, the supply line 21 and the supply pipe 150 are purged by the first inert gas N₂. Accordingly, there is no dead space in which the source gas TiCl₄ remains in the first source-gas valve 80. Additionally, N₂ gas of the supply source 30 continuously flows in the supply line 31.

Next, NH₃ gas, which is the second source gas, is supplied to the substrate 51 so as to be reacted with TiCl₄ adsorbed on the substrate 51. That is, NH₃ gas is supplied to the reaction chamber 50.

In this case, if the diaphragm urging mechanism 86-a, 86-b of the valve 110 urges the diaphragm 83 in the direction toward the box member 84, the second source-gas supply opening 92 is opened to the supply line 31 of N₂ gas. Thus, NH₃ gas supplied by the supply source 40 and flowing through the supply line 121 is supplied to the supply line 31 of N₂ gas via the second source-gas supply opening 92 which is opened. Namely, the NH₃ gas flows in the direction of arrow B in FIG. 3.

On the other hand, N₂ gas supplied by the supply source 30 is continuously supplied to the supply line 31 and continuously flows through the supply line 31. That is, the N₂ gas, which corresponds to the second inert gas, flows continuously in the direction of arrow C indicated by dotted lines in FIG. 3.

Therefore, the NH₃ gas and the N₂ gas are mixed within the supply line 31. The supply line 31 is connected to the supply pipe 150, which is connected to the reaction chamber 50 on the downstream side, and thereby, the NH₃ gas and the N₂ gas are supplied to the reaction chamber 50 through the supply pipe 150.

Moreover, since N₂ gas, which is the first inert gas, is continuously supplied from the supply source 20 to the supply line 21 at the same time, the NH₃ gas, which is the second source gas, is prevented from entering the supply line 91 of TiCl₄ gas, which is the first source gas, thereby preventing mixture of both the first and second source gases.

Next, as shown in FIG. 4, the supply of the NH₃ gas, which is the second source gas, to the reaction chamber 50 is stopped, and the NH₃ gas is purged by N₂ gas from the supply source 30. That is, only N₂ gas is supplied through the supply line 31 and the supply pipe 150.

At this time, when purging the NH₃ gas, the diaphragm urging mechanism 86-a, 86-b urges the diaphragm 83 in the direction toward the box member 84 as shown in FIG. 4 so as to directly and completely close the second source-gas supply opening 92, which is open in the top surface of the protruding part 85 and communicates the supply line 121 of NH₃ gas with the supply line 31 of N₂ gas. Accordingly, the NH₃ gas cannot flow into the supply line 31 through the second source-gas supply opening 92.

On the other hand, N₂ gas continuously flows through the supply line 31 and the supply pipe 150, as is in the case shown in FIG. 3. That is, N₂ gas, which corresponds to the second inert gas, flows around the protruding part 85 in which the second source-gas opening 92 is formed, and flows continuously in the direction of arrow D indicated by dotted lines in FIG. 4.

Therefore, the supply line 31 and the supply pipe 150 are purged by the second inert gas N₂. Accordingly, there is no dead space in which the source gas NH₃ remains in the second source-gas valve 110. Additionally, N₂ gas of the supply source 20 continuously flows in the supply line 21.

The above-mentioned process of alternately supplying TiCl₄ gas and NH₃ gas is repeated so as to deposit a thin film of TiN having a predetermined thickness.

As mentioned above, in the thin-film deposition apparatus according to the present embodiment, the source-gas supply opening 92 for the source gases TiCl₄ and NH₃ directly faces the supply line 21 or 31 of N₂ gas. Therefore, TiCl₄ gas and NH₃ gas flow through the first and second source-gas supply openings 92 of the first and second source-gas valves 80 and 110, respectively, only when depositing a film, by urging the diaphragm 83 in the direction opposite to the direction toward the box member 84, and the-thus supplied TiCl₄ gas and NH₃ gas flow together with N₂ gas in the supply lines 21 and 31, respectively.

Then, when purging, the source-gas supply opening 92 is directly and completely closed by urging the diaphragm 83 in the direction toward the box member 84 so as to prevent TiCl₄ gas and NH₃ gas from flowing into the supply lines 21 and 31, respectively. Therefore, when purging, TiCl₄ gas remaining in the supply line 21 and the NH₃ gas remaining in the supply line 31 can be removed by the flow of the inert gas N₂, respectively. That is, a dead volume in which the source gases can stay and remain can be eliminated, which eliminates diffusion of gases remaining in the supply lines. Therefore, the supply of the source gases can be rapidly switched.

Moreover, since the inert gas N₂ is continuously supplied during deposition of a film and also during a purging operation, purging efficiency of the source gases TiCl₄ and NH₃ remaining in the supply lines 21 and 31 and the supply pipe 150 can be improved as compared to a case where the inert gas N₂ is supplied only after supply of source gases is stopped. Therefore, supply of source gases can be rapidly switched.

Although the preferred embodiment of the present invention was explained, the present invention is not limited to the above-mentioned embodiment.

For example, the flow passage of the first inert gas N₂ for the first source gas TiCl₄ can be commonly used for the flow passage of the second inert gas N₂ for the second source gas NH₃. That is, if the first inert gas for the first source gas and the second inert gas for the second source gas are the same kind of gas, for example, N₂ gas in the above-mentioned embodiment, the flow passages of the first and second inert gases can be made into a single flow passage.

For example, although the valves 80 and 110 are connected in parallel in the above-mentioned embodiment as shown in FIG. 2, the valves 80 and 110 can be connected in series when a single flow passage is used for both the flow passages of the first and second inert gases. In such a case, the piping arrangement of the thin-film deposition apparatus is simplified, which reduces the size of the thin-film deposition apparatus.

Further, the first source gas is not limited to TiCl₄, and TiI₄, Ti[N(CH₃)₂]₄, Ti[N(C₂H₅)₂]₄, TaF₅, TaCl₅, TaBr₅, Ta[N(CH₃)₂]₅, WF₆, W(CO)₆, Cu(hfac)TMVS, Cu(hfac)₂, Al(CH₃)₃, AlCl₃, SiH₄, etc., may be used as the first source gas. It should be noted that the present invention is applicable to a case where the aforementioned gases are alternatively supplied.

Moreover, the second source gas is not limited to NH₃, and H₂, B₂H₆, N₂H₄, O₂, O₃, H₂O, NO, N₂O, etc., may be used as the second source gas.

Further, Ar may be used as the inert gas inactive to the source gases.

The present invention is not limited to the specifically disclosed embodiments, and variations and modifications may be made without departing from the scope of the present invention.

The present application is based on Japanese priority application No. 2002-253670 filed on Aug. 30, 2002, the entire contents of which are hereby incorporated by reference.

What is claimed is:

1. A thin-film deposition apparatus which forms a thin film on a substrate by supplying a plurality of kinds of source gases to a reaction chamber one kind at a time for a plurality of times, comprising:
a supply passage connected to said reaction chamber so as to supply each of the source gases and an inert gas to said reaction chamber; and
a source-gas supply opening provided in said supply passage so as to supply each of the source gases to said supply passage; and
a source-gas valve for opening and closing said source-gas supply opening provided in said supply passage.

2. The thin-film deposition apparatus as claimed in claim 1, wherein said source-gas valve is a diaphragm valve.

3. A thin-film deposition apparatus as claimed in claim 1, wherein the source gases include a first source gas and a second source gas, and the inert gas includes a first inert gas inactive to said first source gas and a second inert gas inactive to said second source gas, and wherein
said supply passage includes:
a first supply passage connected to said reaction chamber so as to supply the first source gas and the first inert gas to said reaction chamber; and
a second supply passage connected to said reaction chamber so as to supply the second source gas and the second inert gas to said reaction chamber,
said source-gas supply opening includes:
a first source-gas supply opening provided in said first supply passage so as to supply the first source gas to said first supply passage; and
a second source-gas supply opening provided in said second supply passage so as to supply the second source gas to said second supply passage,
said source-gas valve includes:
a first source-gas valve provided in said first supply passage so as to open and close said first source-gas supply opening; and
a second source-gas valve provided in said second supply passage so as to open and close said second source-gas supply opening.

4. The thin-film deposition apparatus as claimed in claim 2, wherein each of said first and second source-gas valves is a diaphragm valve.

5. The thin-film deposition apparatus as claimed in claim 2, wherein said first supply passage which supplies the first inert gas is commonly usable as said second supply passage which supplies the second inert gas.

6. The thin-film deposition apparatus as claimed in claim 5, wherein each of said first and second source-gas valves is a diaphragm valve.

7. A thin-film deposition method for depositing a thin film on a substrate placed in a reaction chamber by supplying a plurality of kinds of source gases one kind at a time for a plurality of times, the method comprising continuously supplying an inert gas inactive to the source gases to said reaction chamber while each of the source gases is supplied to said reaction chamber.

8. The thin-film deposition method as claimed in claim 7, wherein the source gases are supplied to a supply passage used for supplying the inert gas to said reaction chamber so as to supply each of the source gases to said reaction chamber together with the inert gas.

9. The thin-film deposition method as claimed in claim 7, wherein the source gases include a first source gas and a second source gas, and the inert gas includes a first inert gas which is inactive to the first source gas and a second inert gas which is inactive to the second source gas, and wherein the first inert gas is continuously supplied to said reaction chamber while the first source gas is supplied to said reaction chamber, and the second inert gas is continuously supplied to said reaction chamber while the second source gas is supplied to said reaction chamber.

10. The thin-film deposition method as claimed in claim 9, wherein both the first inert gas and the second inert gas are continuously supplied to said reaction chamber while the first source gas is supplied to said reaction chamber.
